(19) United States
(12) Patent Application Publication
(10) Pub. No.: US 2024/0275134 A1
(43) Pub. Date: Aug. 15, 2024

(54) SEMICONDUCTOR LASER DEVICE

(71) Applicant: ROHM CO., LTD., Kyoto (JP)

(72) Inventors: Yoshinori TANAKA, Kyoto-shi (JP); Keiji HIDAKA, Kyoto-shi (JP); Junxiong NIU, Kyoto-shi (JP)

(73) Assignee: ROHM CO., LTD., Kyoto (JP)

(21) Appl. No.: 18/644,861

(22) Filed: Apr. 24, 2024

Related U.S. Application Data
(63) Continuation of application No. PCT/JP2022/035934, filed on Sep. 27, 2022.

(30) Foreign Application Priority Data
Oct. 27, 2021 (JP) 2021-175788

(51) Int. Cl. H01S 5/343; H01S 5/22; H01S 5/34

(52) U.S. Cl. CPC H01S 5/34313; H01S 5/22; H01S 5/3416; H01S 5/34353

(57) ABSTRACT

A semiconductor laser device includes a light emitting unit including an active layer and an n-type semiconductor layer and a p-type semiconductor layer that sandwich the active layer. The n-type semiconductor layer includes a first n-type cladding layer and a second n-type cladding layer. The p-type semiconductor layer includes a first p-type cladding layer and a second p-type cladding layer. The n-type semiconductor layer has a greater thickness than the p-type semiconductor layer. An n-type thickness ratio, which is a ratio of a thickness of the first n-type cladding layer to a thickness of the second n-type cladding layer, is equal to a p-type thickness ratio, which is a ratio of a thickness of the first p-type cladding layer to a thickness of the second p-type cladding layer. The n-type thickness ratio and the p-type thickness ratio are each greater than 1.25 and less than or equal to 3.75.

### BACKGROUND

The following description relates to a semiconductor laser device.

Japanese Laid-Open Patent Publication No. 2019-186387 discloses a semiconductor laser device. The semiconductor laser device has a double heterostructure including an n-type cladding layer, an active layer, and a p-type cladding layer. The semiconductor laser device emits laser light from an end surface of the active layer.

### BRIEF DESCRIPTION OF THE DRAWINGS

FIG. 1 is a perspective view showing one embodiment of a semiconductor laser device.

FIG. 2 is a cross-sectional view of the semiconductor laser device shown in FIG. 1.

FIG. 3 is a diagram showing an example of the structure of a light emitting unit shown in FIG. 2.

FIG. 4 is a diagram showing an example of the structure of an active layer shown in FIG. 3.

FIG. 5 is a diagram showing an example of the structure of a tunnel layer shown in FIG. 2.

FIG. 6 is a diagram showing a state of laser light emitted from the semiconductor laser device shown in FIG. 1.

FIG. 7 is a diagram showing a state of laser light in the light emitting unit.

FIG. 8 is a diagram showing a far field pattern of the semiconductor laser device shown in FIG. 1.

FIG. 9 is a table showing thicknesses of cladding layers, FFP (angle), optical output (relative value), and thickness ratio in embodiments of the semiconductor laser device.

FIG. 10 is a cross-sectional view showing a modified example of a semiconductor laser device.

FIG. 11 is a cross-sectional view showing a modified example of a semiconductor laser device.

### DETAILED DESCRIPTION

Embodiments of a semiconductor laser device according to the present disclosure will be described below with reference to the drawings. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### EMBODIMENTS

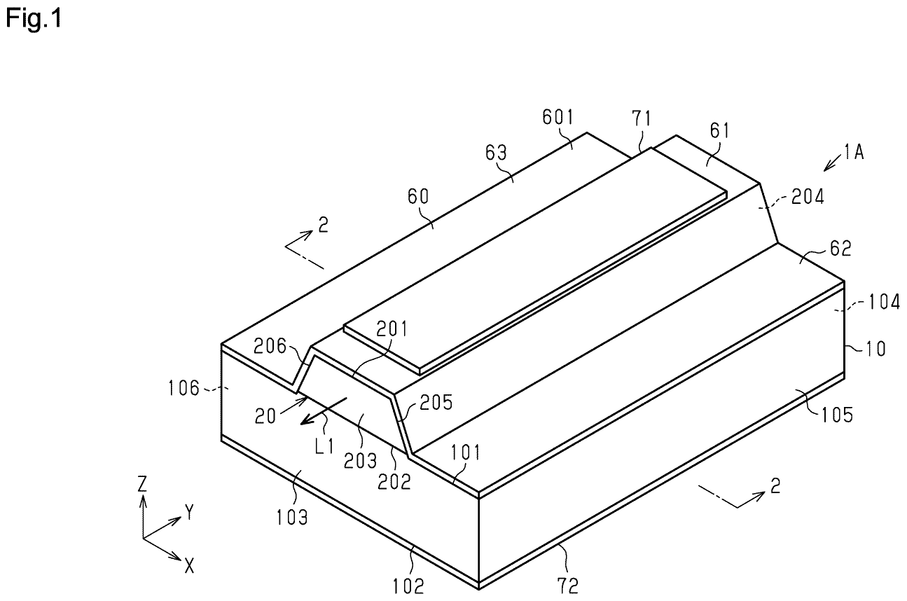

One embodiment of a semiconductor laser device 1A will be described with reference to FIGS. 1 to 9.

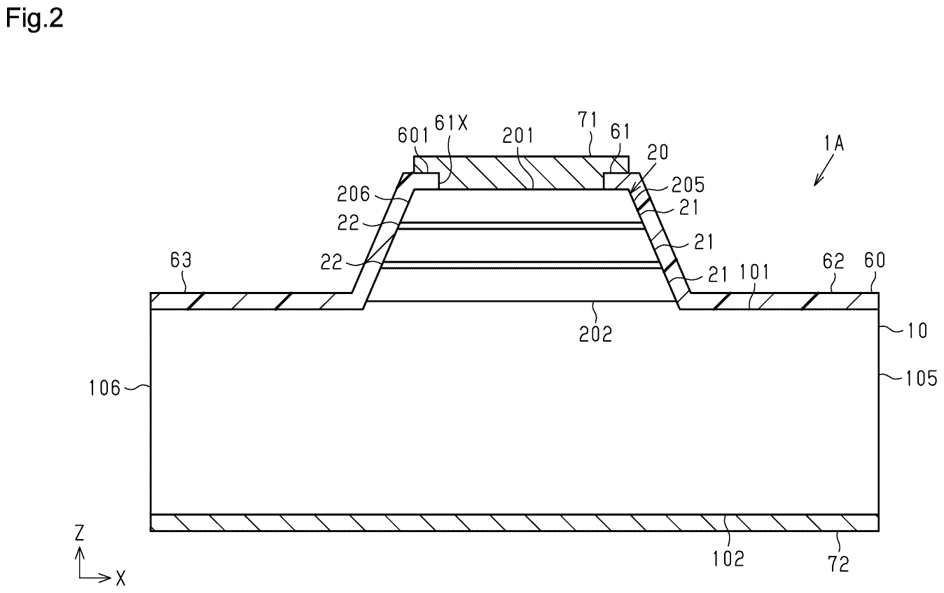

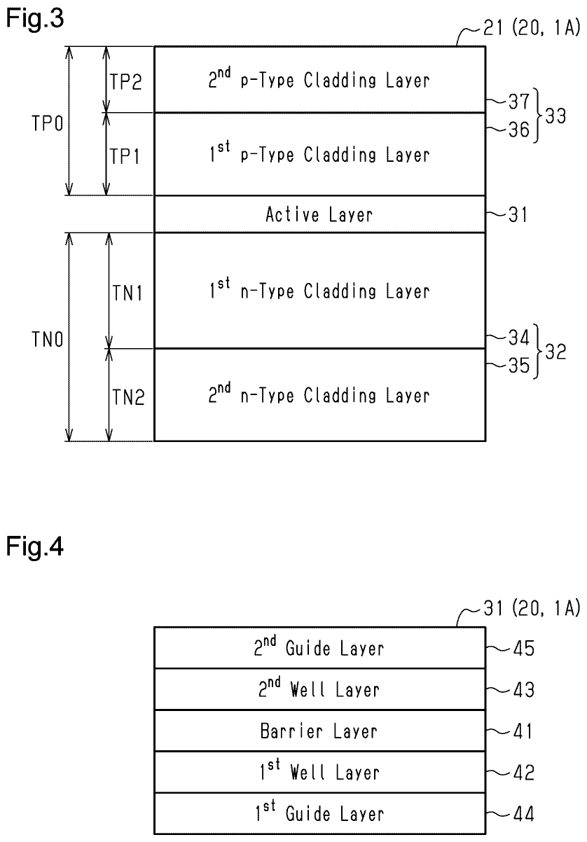

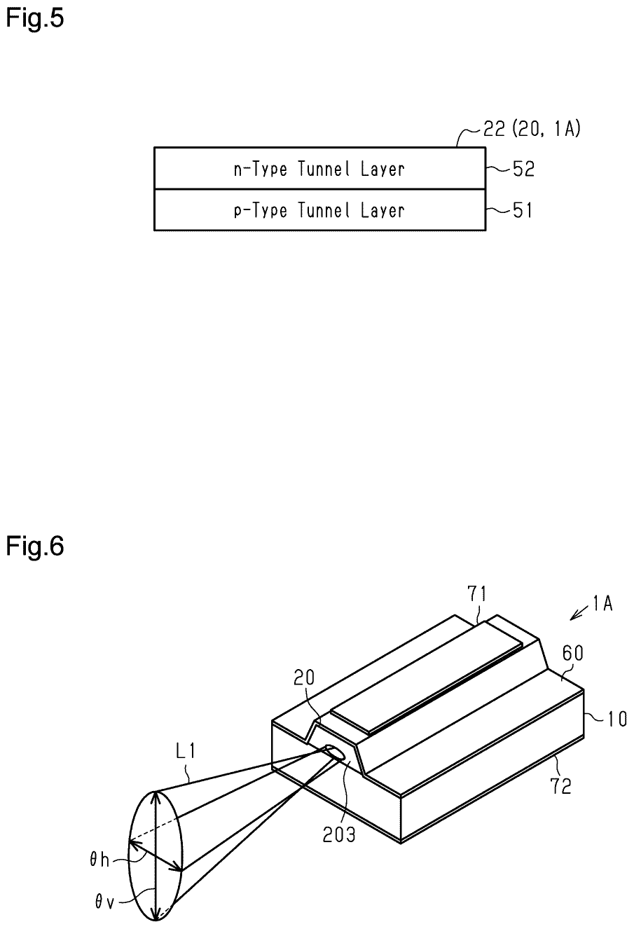

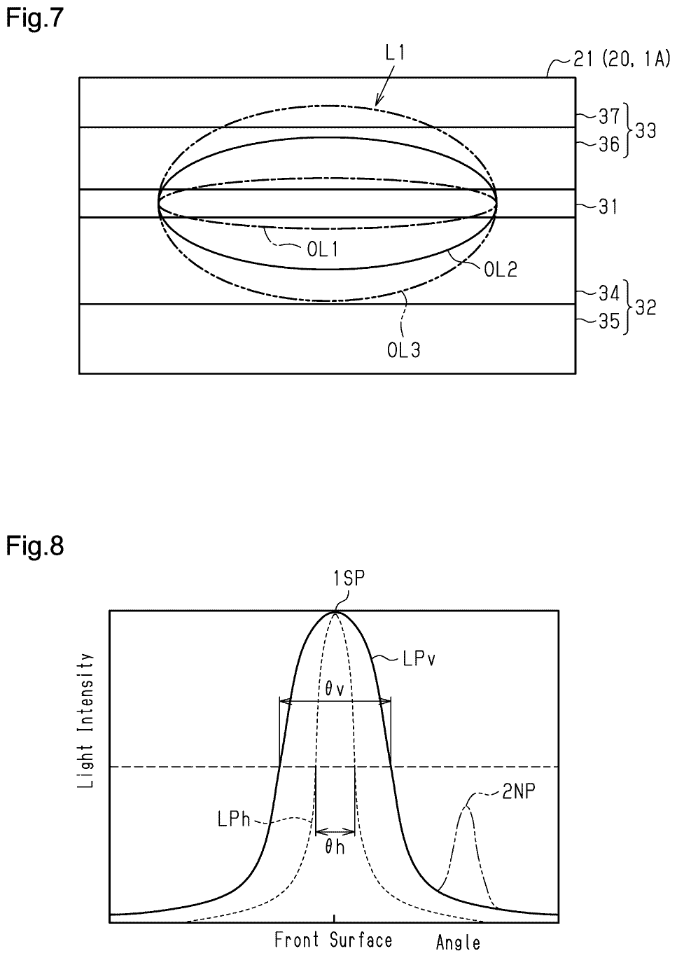

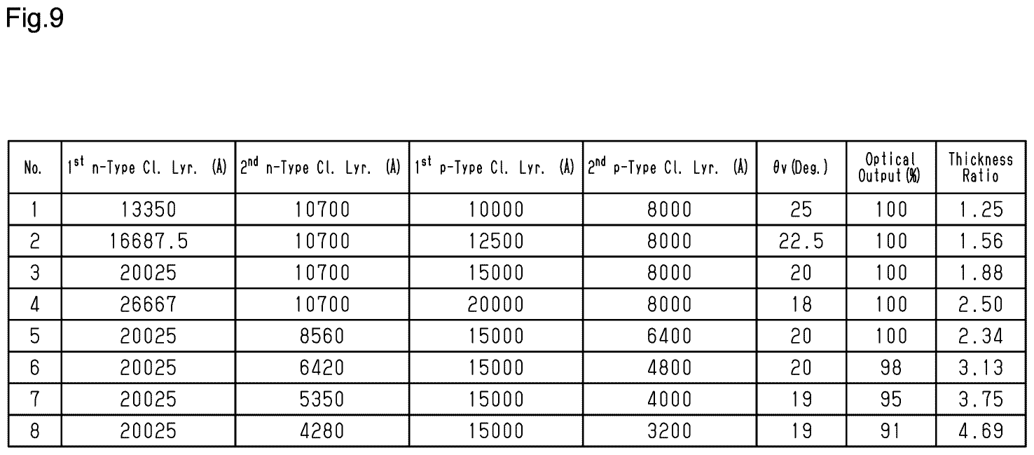

FIG. 1 is a perspective view showing one embodiment of a semiconductor laser device. FIG. 2 is a cross-sectional view of the semiconductor laser device shown in FIG. 1. FIG. 3 is a diagram showing an example of the structure of a light emitting unit shown in FIG. 2. FIG. 4 is a diagram showing an example of the structure of an active layer shown in FIG. 3. FIG. 5 is a diagram showing an example of the structure of a tunnel layer shown in FIG. 2. FIG. 6 is a diagram showing an emission pattern of laser light emitted from the semiconductor laser device shown in FIG. 1. FIG. 7 is a diagram showing a state of laser light in the light emitting unit. FIG. 8 is a diagram showing a far field pattern of the semiconductor laser device shown in FIG. 1. In FIG. 8, the horizontal axis represents an angle with a front surface of the light emitting unit centered. The vertical axis represents light intensity (output of laser light). FIG. 9 is a table showing thicknesses of cladding layers, FFP (angle), an optical output relative value, and thickness ratio in embodiments of the semiconductor laser device.

### Semiconductor Laser Device: Overall Structure

As shown in FIGS. 1 and 2, a semiconductor laser device 1A includes a semiconductor substrate 10, a light emitter 20, an insulation film 60, a first electrode 71, and a second electrode 72.

The semiconductor substrate 10 includes a substrate main surface 101, a substrate back surface 102, and substrate side surfaces 103, 104, 105, and 106. The substrate main surface 101 and the substrate back surface 102 face opposite directions. A direction perpendicular to the substrate main surface 101 is referred to as the Z-direction (thickness-wise direction, first direction). A direction orthogonal to the Z-direction is referred to as the X-direction (third direction). A direction orthogonal to the Z-direction and the X-direction is referred to as the Y-direction (second direction). The substrate side surfaces 103 and 104 face opposite directions in the Y-direction. The substrate side surfaces 105 and 106 face opposite directions in the X-direction. As viewed in the Z-direction, the semiconductor substrate 10 is rectangular and elongated in the Y-direction.

In the present embodiment, the semiconductor substrate 10 is rectangular-plate-shaped. In the present embodiment, the semiconductor substrate 10 includes an n-type semiconductor substrate (n-GaAs substrate) including gallium-arsenic (GaAs). The semiconductor substrate 10 includes, for example, at least one of silicon (Si), tellurium (Te), or selenium (Se) as an n-type impurity.

The light emitter 20 is arranged on the substrate main surface 101 of the semiconductor substrate 10. The light emitter 20 projects from the substrate main surface 101 in a direction away from the substrate back surface 102.

The light emitter 20 includes an electrode connection surface 201, a substrate connection surface 202, light emitter end surfaces 203 and 204, and light emitter side surfaces 205 and 206. The electrode connection surface 201 and the substrate main surface 101 face the same direction in the Z-direction. The substrate connection surface 202 faces toward the semiconductor substrate 10 and is connected to the substrate main surface 101. The light emitter side surfaces 205 and 206 face opposite directions in the X-direction. The light emitter end surfaces 203 and 204 face opposite directions in the Y-direction. The light emitter side surfaces 205 and 206 connect the electrode connection surface 201 and the substrate main surface 101. The light emitter end surfaces 203 and 204 define resonator end surfaces. The Y-direction may be referred to as a resonator direction of the light emitter 20.

In the present embodiment, the light emitter 20 includes a mesa structure that is trapezoidal (ridged) and projects from the substrate main surface 101 as viewed in the Y-direction. The light emitter side surface 205 is inclined toward the electrode connection surface 201 with respect to a direction in which the substrate side surface 105 faces. The light emitter side surface 206 is inclined toward the electrode connection surface 201 with respect to a direction in which the substrate side surface 106 faces. As viewed in the Y-direction, the light emitter 20 is trapezoidal so that the electrode connection surface 201, which is located at one side in the Z-direction, has a smaller width than the substrate connection surface 202, which is connected to the substrate main surface 101. As shown in FIG. 1, the light emitter 20 extends in the Y-direction. In the present embodiment, the light emitter 20 has the same length in the Y-direction as the semiconductor substrate 10. Thus, the light emitter end surface 203 of the light emitter 20 is flush with the substrate side surface 103 of the semiconductor substrate 10. Also, the light emitter end surface 204 of the light emitter 20 is flush with the substrate side surface 104 of the semiconductor substrate 10.

The insulation film 60 covers part of the substrate main surface 101 of the semiconductor substrate 10. The insulation film 60 covers the light emitter 20. In the present embodiment, the insulation film 60 covers the electrode connection surface 201 and the light emitter side surfaces 205 and 206 of the light emitter 20. In the present embodiment, the insulation film 60 includes substrate covers 62 and 63 covering the substrate main surface 101 of the semiconductor substrate 10 and a light emitter cover 61 covering the light emitter 20. The insulation film 60 is composed of, for example, silicon nitride (SiN) or silicon oxide (SiO₂).

As shown in FIGS. 1 and 2, the insulation film 60 includes an upper surface 601 covering the electrode connection surface 201 of the light emitter 20. The first electrode 71 is arranged on the upper surface 601. As shown in FIG. 2, the insulation film 60, which covers the electrode connection surface 201 of the light emitter 20, includes a first opening 61X exposing part of the electrode connection surface 201. The first electrode 71 is electrically connected to the electrode connection surface 201 exposed from the first opening 61X in the insulation film 60. Thus, the first electrode 71 is electrically connected to the light emitter 20. The first electrode 71 covers edges of the insulation film 60 defining the first opening 61X.

The first electrode 71 may include multiple electrode layers. In an example, the first electrode 71 includes a first electrode layer and a second electrode layer. The first electrode layer and the second electrode layer are stacked in this order from the side of the electrode connection surface 201. The first electrode layer includes, for example, a titanium (Ti) layer and a gold (Au) layer. The second electrode layer includes, for example, a plating layer including Au.

As shown in FIGS. 1 and 2, the second electrode 72 is arranged on the substrate back surface 102 of the semiconductor substrate 10. In the present embodiment, the second electrode 72 covers the entirety of the substrate back surface 102. The second electrode 72 is electrically connected to the semiconductor substrate 10.

The second electrode 72 may include multiple electrode layers.

The second electrode 72 may include at least one of a nickel (Ni) layer, a gold-germanium (AuGe) alloy layer, a titanium (Ti) layer, or a gold (Au) layer. In an example, the second electrode 72 may include a Ni layer, a AuGe layer, a Ti layer, and a Au layer that are sequentially stacked from the substrate back surface 102.

### Light Emitter

As shown in FIG. 2, the light emitter 20 includes a light emitting unit 21 formed on the substrate main surface 101 of the semiconductor substrate 10. The light emitting unit 21 combines holes and electrons to generate light. In the present embodiment, the light emitter 20 includes three light emitting units 21. The light emitter 20 may include at least one light emitting unit 21. That is, the number of the light emitting units 21 may be one, two, four or more.

In the present embodiment, the light emitter 20 includes tunnel layers 22 located between adjacent ones of the light emitting units 21. The tunnel layers 22 generate tunnel current due to the tunnel effect and supply the tunnel current to the light emitting units 21. In the present embodiment, the light emitter 20 includes two tunnel layers 22. Each tunnel layer 22 is located between two of the light emitting units 21 located adjacent to each other.

### Light Emitting Unit

FIG. 3 is a diagram showing the structure of the light emitting unit 21.

The light emitting unit 21 includes an active layer 31 and an n-type semiconductor layer 32 and a p-type semiconductor layer 33 that sandwich the active layer 31 in the thickness-wise direction of the active layer 31. The n-type semiconductor layer 32 is located at a side of the active layer 31 close to the semiconductor substrate 10 shown in FIGS. 1 and 2. The p-type semiconductor layer 33 is located at a side of the active layer 31 opposite from the n-type semiconductor layer 32, that is, close to the first electrode 71 shown in FIGS. 1 and 2. In other words, the light emitting unit 21 has a stack structure including the n-type semiconductor layer 32, the active layer 31, and the p-type semiconductor layer 33 that are sequentially stacked from the side of the semiconductor substrate 10. A thickness TN0 of the n-type semiconductor layer 32 is greater than a thickness TP0 of the p-type semiconductor layer 33. A thickness ratio RTNP of the thickness TN0 of the n-type semiconductor layer 32 to the thickness TP0 of the p-type semiconductor layer 33 is, for example, in a range of 1.3 to 1.4. More preferably, the thickness ratio RTNP is in a range of 1.33 to 1.34.

### n-Type Semiconductor Layer

The n-type semiconductor layer 32 includes aluminum-gallium-arsenic (AlGaAs). The n-type semiconductor layer 32 includes, for example, at least one of Si, Te, or Se as an n-type impurity. The concentration of the impurity in the n-type semiconductor layer 32 is, for example, in a range of 1×10¹⁷ cm⁻³ to 1×10¹⁹ cm⁻³.

The n-type semiconductor layer 32 includes a first n-type cladding layer 34 and a second n-type cladding layer 35. The first n-type cladding layer 34 is located adjacent to the active layer 31. The second n-type cladding layer 35 and the active layer 31 are located at opposite sides of the first n-type cladding layer 34. In other words, the n-type semiconductor layer 32 includes the first n-type cladding layer 34, which is located adjacent to the active layer 31, and the second n-type cladding layer 35, which is located at a side of the first n-type cladding layer 34 opposite from the active layer 31. In other words, the n-type semiconductor layer 32 includes the first n-type cladding layer 34 and the second n-type cladding layer 35 stacked in this order from the side of the active layer 31.

The first n-type cladding layer 34 includes Al_{A1}Ga_{(1-A1)}As having an Al composition A1. The Al composition A1 of the first n-type cladding layer 34 is in a range of 0.3 to 0.4. The second n-type cladding layer 35 includes Al_{A2}Ga_{(1-A2)}As having an Al composition A2 that differs from the Al composition A1 of the first n-type cladding layer 34. More specifically, the Al composition A2 of the second n-type cladding layer 35 is greater than the Al composition A1 of the first n-type cladding layer 34 (A2>A1). The Al composition A2 of the second n-type cladding layer 35 is in a range of 0.5 to 0.6.

In the present embodiment, the impurity concentration of the second n-type cladding layer 35 differs from the impurity concentration of the first n-type cladding layer 34. More specifically, the impurity concentration of the second n-type cladding layer 35 is greater than the impurity concentration of the first n-type cladding layer 34. The impurity concentration of the second n-type cladding layer 35 may be equal to the impurity concentration of the first n-type cladding layer 34. The impurity concentration of the second n-type cladding layer 35 may be less than the impurity concentration of the first n-type cladding layer 34.

A thickness TN2 of the second n-type cladding layer 35 differs from a thickness TN1 of the first n-type cladding layer 34. More specifically, the thickness TN2 of the second n-type cladding layer 35 is less than the thickness TN1 of the first n-type cladding layer 34. An n-type thickness ratio RTn (=TN1/TN2) of the thickness TN1 of the first n-type cladding layer 34 to the thickness TN2 of the second n-type cladding layer 35 is greater than 1.25 and less than or equal to 3.75. The thickness TN1 of the first n-type cladding layer 34 may be in a range of 13000 angstroms to 27000 angstroms. The thickness TN2 of the second n-type cladding layer 35 may be in a range of 5000 angstroms to 11000 angstroms.

### p-Type Semiconductor Layer

The p-type semiconductor layer 33 includes AlGaAs. The p-type semiconductor layer 33 includes, for example, carbon (C) as a p-type impurity. The concentration of the impurity in the p-type semiconductor layer 33 is, for example, in a range of 1×10¹⁷ cm⁻³ to 1×10¹⁹ cm⁻³.

The p-type semiconductor layer 33 includes a first p-type cladding layer 36 and a second p-type cladding layer 37. The first p-type cladding layer 36 is located adjacent to the active layer 31. The second p-type cladding layer 37 and the active layer 31 are located at opposite sides of the first p-type cladding layer 36. In other words, the p-type semiconductor layer 33 includes the first p-type cladding layer 36, which is located adjacent to the active layer 31, and the second p-type cladding layer 37, which is located at a side of the first p-type cladding layer 36 opposite from the active layer 31. In other words, the p-type semiconductor layer 33 includes the first p-type cladding layer 36 and the second p-type cladding layer 37 stacked in this order from the side of the active layer 31.

The first p-type cladding layer 36 includes Al_{B1}Ga_{(1-B1)}As having an Al composition B1. The Al composition B1 of the first p-type cladding layer 36 is in a range of 0.3 to 0.4. The second p-type cladding layer 37 includes Al_{B2}Ga_{(1-B2)}As having an Al composition B2 that differs from the Al composition B1 of the first p-type cladding layer 36. More specifically, the Al composition B2 of the second p-type cladding layer 37 is greater than the Al composition B1 of the first p-type cladding layer 36 (B2>B1). The Al composition B2 of the second p-type cladding layer 37 is in a range of 0.5 to 0.6.

In the present embodiment, the impurity concentration of the second p-type cladding layer 37 differs from the impurity concentration of the first p-type cladding layer 36. More specifically, the impurity concentration of the second p-type cladding layer 37 is greater than the impurity concentration of the first p-type cladding layer 36. The impurity concentration of the second p-type cladding layer 37 may be equal to the impurity concentration of the first p-type cladding layer 36. The impurity concentration of the second p-type cladding layer 37 may be less than the impurity concentration of the first p-type cladding layer 36.

A thickness TP2 of the second p-type cladding layer 37 differs from a thickness TP1 of the first p-type cladding layer 36. More specifically, the thickness TP2 of the second p-type cladding layer 37 is less than the thickness TP1 of the first p-type cladding layer 36. A p-type thickness ratio RTp (=TP1/TP2) of the thickness TP1 of the first p-type cladding layer 36 to the thickness TP2 of the second p-type cladding layer 37 is greater than 1.25 and less than or equal to 3.75. The thickness TP1 of the first p-type cladding layer 36 may be in a range of 10000 angstroms to 20000 angstroms. The thickness TP2 of the second p-type cladding layer 37 may be in a range of 4000 angstroms to 8000 angstroms.

### Active Layer

FIG. 4 is a diagram showing an example of the structure of the active layer 31.

The active layer 31 has a multiple quantum well structure that includes a barrier layer 41, a first well layer 42, and a second well layer 43. In the present embodiment, the active layer 31 includes the barrier layer 41, the first well layer 42, the second well layer 43, a first guide layer 44, and a second guide layer 45.

The first well layer 42 and the second well layer 43 are located at opposite sides of the barrier layer 41. The first well layer 42 is located adjacent to the barrier layer 41 at a side of the barrier layer 41 close to the n-type semiconductor layer 32 shown in FIG. 3. The second well layer 43 and the first well layer 42 are located at opposite sides of the barrier layer 41. In other words, the first well layer 42, the barrier layer 41, and the second well layer 43 are stacked in this order from the n-type semiconductor layer 32 (the first n-type cladding layer 34) shown in FIG. 3.

The first guide layer 44 is located adjacent to the first well layer 42. The first guide layer 44 and the barrier layer 41 are located at opposite sides of the first well layer 42. The second guide layer 45 is located adjacent to the second well layer 43. The second guide layer 45 and the barrier layer 41 are located at opposite sides of the second well layer 43. In other words, the first guide layer 44 and the second guide layer 45 sandwich the first well layer 42, the barrier layer 41, and the second well layer 43. In other words, in the present embodiment, the active layer 31 includes the first guide layer 44, the first well layer 42, the barrier layer 41, the second well layer 43, and the second guide layer 45 that are stacked in this order from the n-type semiconductor layer 32 (the first n-type cladding layer 34) shown in FIG. 3.

The barrier layer 41 includes AlGaAs. The barrier layer 41 includes Al_{C1}Ga_{(1-C1)}As having an Al composition C1. The Al composition C1 of the barrier layer 41 differs from the Al composition (Al compositions A1 and A2) of the n-type semiconductor layer 32 and the Al composition (Al compositions B1 and B2) of the p-type semiconductor layer 33. The Al composition C1 of the barrier layer 41 is less than the Al composition (Al compositions A1 and A2) of the n-type semiconductor layer 32 and the Al composition (Al compositions B1 and B2) of the p-type semiconductor layer 33. In an example, the Al composition C1 of the barrier layer 41 is in a range of 0.05 to 0.15. The barrier layer 41 may not be doped.

The first well layer 42 includes In_{D1}Ga_{(1-D1)}As having an In composition D1. The In composition D1 is greater than 0 and less than or equal to 0.15. The first well layer 42 may not be doped.

The second well layer 43 includes In_{D2}Ga_{(1-D2)}As having an In composition D2. The In composition D2 is greater than 0 and less than or equal to 0.15. The second well layer 43 may not be doped.

The first guide layer 44 includes AlGaAs. The first guide layer 44 includes Al_{C2}Ga_{(1-C2)}As having an Al composition C2. The Al composition C2 of the first guide layer 44 differs from the Al composition (Al compositions A1 and A2) of the n-type semiconductor layer 32. The Al composition C2 of the first guide layer 44 is less than the Al composition (the Al compositions A1 and A2) of the n-type semiconductor layer 32. In an example, the Al composition C2 of the first guide layer 44 is in a range of 0.05 to 0.15. The first guide layer 44 may not be doped.

The second guide layer 45 includes AlGaAs. The second guide layer 45 includes Al_{C3}Ga_{(1-C3)}As having an Al composition C3. The Al composition C3 of the second guide layer 45 differs from the Al composition (Al compositions B1 and B2) of the p-type semiconductor layer 33. The Al composition C3 of the second guide layer 45 is less than the Al composition (Al compositions B1 and B2) of the p-type semiconductor layer 33. In an example, the Al composition C3 of the second guide layer 45 is in a range of 0.05 to 0.15. The second guide layer 45 may not be doped.

### Tunnel Layer

FIG. 5 is a diagram showing an example of the structure of the tunnel layer 22.

The tunnel layer 22 includes a p-type tunnel layer 51 and an n-type tunnel layer 52. The p-type tunnel layer 51 is located adjacent to the p-type semiconductor layer 33 (the second p-type cladding layer 37) shown in FIG. 3. The n-type tunnel layer 52 is located adjacent to the n-type semiconductor layer 32 (the second n-type cladding layer 35) shown in FIG. 3. Thus, the p-type tunnel layer 51 and the n-type tunnel layer 52 are stacked in this order from the side of the semiconductor substrate 10 shown in FIGS. 1 and 2. Each tunnel layer 22 is arranged between the light emitting units 21 so that the p-type tunnel layer 51 is electrically connected to the p-type semiconductor layer 33 shown in FIG. 3 and the n-type tunnel layer 52 is electrically connected to the n-type semiconductor layer 32 shown in FIG. 3.

The p-type tunnel layer 51 includes GaAs. The p-type tunnel layer 51 includes, for example, C as a p-type impurity. The concentration of the impurity in the p-type tunnel layer 51 differs from the concentration of the impurity in the p-type semiconductor layer 33. The concentration of the impurity in the p-type tunnel layer 51 is higher than the concentration of the impurity in the p-type semiconductor layer 33.

The n-type tunnel layer 52 includes GaAs. The n-type tunnel layer 52 includes, for example, at least one of Si, Te, or Se as an n-type impurity. The concentration of the impurity in the n-type tunnel layer 52 differs from the concentration of the impurity in the n-type semiconductor layer 32. The concentration of the impurity in the n-type tunnel layer 52 is higher than the concentration of the impurity in the n-type semiconductor layer 32.

### Operation

The operation of the semiconductor laser device 1A will now be described.

In the present embodiment, the semiconductor laser device 1A includes the light emitting unit 21 including the active layer 31 and the n-type semiconductor layer 32 and the p-type semiconductor layer 33 that sandwich the active layer 31 in the thickness-wise direction of the active layer 31 (Z-direction). The semiconductor laser device 1A emits light from the active layer 31. The n-type semiconductor layer 32 includes the first n-type cladding layer 34, which is located adjacent to the active layer 31, and the second n-type cladding layer 35, which is located at a side of the first n-type cladding layer 34 opposite from the active layer 31. The p-type semiconductor layer 33 includes the first p-type cladding layer 36, which is located adjacent to the active layer 31, and the second p-type cladding layer 37, which is located at a side of the first p-type cladding layer 36 opposite from the active layer 31. The thickness TN0 of the n-type semiconductor layer 32 is greater than the thickness TP0 of the p-type semiconductor layer 33. The n-type thickness ratio RTn, which is the ratio of the thickness TN1 of the first n-type cladding layer 34 to the thickness TN2 of the second n-type cladding layer 35, is equal to the p-type thickness ratio RTp, which is the ratio of the thickness TP1 of the first p-type cladding layer 36 to the thickness TP2 of the second p-type cladding layer 37. The n-type thickness ratio RTn and the p-type thickness ratio RTp are greater than 1.25 and less than or equal to 3.75.

In the active layer 31 of the semiconductor laser device 1A, electrons from the n-type semiconductor layer 32 recombine with holes from the p-type semiconductor layer 33. As a result, light is generated in the active layer 31. As the light generated in the active layer 31 repeats stimulated emission between the resonator end surfaces, which are the light emitter end surfaces 203 and 204 of the light emitter 20 defining end surfaces of the active layer 31, the light is resonantly amplified. A portion of the amplified light is emitted as laser light L1 from the resonator end surfaces, that is, the light emitter end surfaces 203 and 204 of the light emitter 20.

FIG. 6 is a schematic diagram of the laser light L1 emitted from the light emitter 20. In FIG. 6, the laser light L1 is emitted from a single light emitting unit 21.

As shown in FIG. 6, on the light emitter end surface 203 of the light emitter 20, the laser light L1 emitted from the light emitter 20 has the form of an ellipse that is elongated in a direction (X-direction) parallel to the active layer 31. At a location separated from the light emitter end surface 203 of the light emitter 20, the laser light L1 has the form of an ellipse that is elongated in a direction (Z-direction) perpendicular to the active layer 31.

The emission pattern property (divergence) of the laser light L1 emitted from the light emitter end surface 203 of the light emitter 20 is expressed as an angle of far field pattern (FFP). The FFP of the laser light L1 is indicated by a first angle θv (degrees) in the thickness-wise direction of the active layer 31 and a second angle θh (degrees) in a direction parallel to the active layer 31. As shown in FIG. 8, the first angle θv and the second angle θh each correspond to full width half maximum (FWHM) of the intensity of the laser light L1. The solid line shown in FIG. 8 indicates an angle-light intensity characteristic line Lpv of the laser light L1 in a direction (Z-direction) perpendicular to the active layer 31. The broken line shown in FIG. 8 indicates an angle-light intensity characteristic line LPh of the laser light L1 in a direction (X-direction) parallel to the active layer 31.

The light resonantly amplified in the active layer 31 shown in FIG. 3 travels into the n-type semiconductor layer 32 and the p-type semiconductor layer 33, which are located adjacent to the active layer 31. The n-type semiconductor layer 32 and the p-type semiconductor layer 33 have an effect of confining the light travelled from the active layer 31.

In the present embodiment, the n-type semiconductor layer 32 includes the first n-type cladding layer 34, which is located adjacent to the active layer 31, and the second n-type cladding layer 35, which is located adjacent to the first n-type cladding layer 34. In the present embodiment, the p-type semiconductor layer 33 includes the first p-type cladding layer 36, which is located adjacent to the active layer 31, and the second p-type cladding layer 37, which is located adjacent to the first p-type cladding layer 36.

The n-type thickness ratio RTn of the first n-type cladding layer 34 to the second n-type cladding layer 35 is greater than 1.25 and less than or equal to 3.75. The first n-type cladding layer 34 and the second n-type cladding layer 35 allow traveling of light from the active layer 31 while restricting traveling of light to a desired range. The p-type thickness ratio RTp of the first p-type cladding layer 36 to the second p-type cladding layer 37 is also greater than 1.25 and less than or equal to 3.75. The first p-type cladding layer 36 and the second p-type cladding layer 37 allow traveling of light from the active layer 31 while restricting traveling of light to a desired range.

FIG. 7 is a schematic diagram showing the shape of the laser light L1 on the end surface of the light emitting unit 21 (the light emitter end surface 203 of the light emitter 20).

When the confining effect of the n-type semiconductor layer 32 and the p-type semiconductor layer 33 to the active layer 31 is high, the shape of the laser light L1 is an ellipse that is elongated in a direction parallel to the active layer 31 as indicated by the single-dashed line OL1 in FIG. 7.

When the traveling of light from the active layer 31 into the n-type semiconductor layer 32 and the p-type semiconductor layer 33 is allowed, the laser light L1 emitted from the light emitting unit 21 is increased in size in a direction perpendicular to the active layer 31 as indicated by the solid line OL2 shown in FIG. 7. This decreases the first angle θv of FFP of the laser light L1 emitted from the light emitter 20 (the light emitting unit 21). In the present embodiment, the first angle θv of FFP of the laser light L1 emitted from the light emitter 20 is less than 25 degrees. Thus, divergence of the laser light L1 when emitted is limited. As described above, the semiconductor laser device 1A of the present embodiment improves the emission pattern property of the laser light L1 when emitted.

In addition, the first n-type cladding layer 34 and the second n-type cladding layer 35 of the n-type semiconductor layer 32, which have the n-type thickness ratio RTn, restrict traveling of light to the desired range. Also, the first p-type cladding layer 36 and the second p-type cladding layer 37 of the p-type semiconductor layer 33, which have the p-type thickness ratio RTp, restrict traveling of light to the desired range. This avoids an undue size increase of the laser light L1 in a direction perpendicular to the active layer 31 as indicated by the double-dashed line OL3 shown in FIG. 7. Thus, a decrease in the output of the laser light L1 when emitted is limited.

In the semiconductor laser device 1A of the present embodiment, the n-type thickness ratio RTn is equal to the p-type thickness ratio RTp. If the n-type thickness ratio RTn differs from the p-type thickness ratio RTp, a peak 2NP may appear at a position shifted from the center as indicated by the double-dashed line shown in FIG. 8. In the present embodiment, the semiconductor laser device 1A emits the laser light L1 having a single peak 1SP in a direction perpendicular to the active layer 31.

The semiconductor laser device 1A is used in, for example, laser systems such as a light detection and ranging, or a laser imaging detection and ranging (LiDAR), which is an example of three dimensional distance measurement, and two dimensional distance measurement. In such a laser system, the laser light L1 emitted from the semiconductor laser device 1A is coupled to a lens to become, for example, parallel light. The first angle θv and the second angle θh of FFP of the laser light L1 affect the coupling efficiency to a lens. When the first angle θv and the second angle θh are large, the amount of the laser light L1 deviated from the lens is increased, and the laser light L1 is used less efficiently. In the semiconductor laser device 1A of the present embodiment, the first angle θv of FFP of the emitted laser light L1 is less than 25 degrees. Thus, the coupling efficiency of the laser light L1 to the lens is improved.

### EXPERIMENTAL EXAMPLES

The thicknesses (thickness ratios RTn and RTp) of the first n-type cladding layer 34, the second n-type cladding layer 35, the first p-type cladding layer 36, and the second p-type cladding layer 37, FFP, and optical output will be described with reference to FIG. 9.

FIG. 9 is a table showing FFP (first angle θv (degree)), optical output (%), and a thickness ratio of semiconductor laser devices in first to eighth experimental examples (Nos. 1 to 8). In FIG. 9, in the optical output (%), the optical output of the first experimental example (No. 1) is used as the reference, and the ratio of the optical output of the second to eighth experimental examples to the reference optical output is expressed as a change rate (%).

In the first to fourth experimental examples, the thickness TN2 of the second n-type cladding layer 35 and the thickness TP2 of the second p-type cladding layer 37 were constant. The thickness TN1 of the first n-type cladding layer 34 and the thickness TP1 of the first p-type cladding layer 36 were changed. In the fifth to eighth experimental examples, the thickness TN1 of the first n-type cladding layer 34 and the thickness TP1 of the first p-type cladding layer 36 were constant. The thickness TN2 of the second n-type cladding layer 35 and the thickness TP2 of the second p-type cladding layer 37 were changed.

In the first experimental example, the n-type thickness ratio RTn and the p-type thickness ratio RTp were 1.25. The first angle θv of FFP was 25 degrees. The optical output of the first experimental example is used as the reference (100%).

In the second experimental example, the n-type thickness ratio RTn and the p-type thickness ratio RTp were 1.56. The first angle θv of FFP was 22.5 degrees. In the second experimental example, the optical output was the same as that in the first experimental example.

In the third experimental example, the n-type thickness ratio RTn and the p-type thickness ratio RTp were 1.88. The first angle θv of FFP was 20 degrees. In the third experimental example, the optical output was the same as that in the first experimental example.

In the fourth experimental example, the n-type thickness ratio RTn and the p-type thickness ratio RTp were 2.50. The first angle θv of FFP was 18 degrees. In the fourth experimental example, the optical output was the same as that in the first experimental example.

In the fifth experimental example, the n-type thickness ratio RTn and the p-type thickness ratio RTp were 2.34. The first angle θv of FFP was 20 degrees. In the fifth experimental example, the optical output was the same as that in the first experimental example.

In the sixth experimental example, the n-type thickness ratio RTn and the p-type thickness ratio RTp were 3.13. The first angle θv of FFP was 20 degrees. In the sixth experimental example, the optical output was 98% of the first experimental example.

In the seventh experimental example, the n-type thickness ratio RTn and the p-type thickness ratio RTp were 3.75. The first angle θv of FFP was 19 degrees. In the seventh experimental example, the optical output was 95% of the first experimental example.

In the eighth experimental example, the n-type thickness ratio RTn and the p-type thickness ratio RTp were 4.89. The first angle θv of FFP was 19 degrees. In the eighth experimental example, the optical output was 91% of the first experimental example.

As shown in the first to fourth experimental examples, when the n-type thickness ratio RTn and the p-type thickness ratio RTp are increased from 1.25, the first angle θv of FFP is decreased without decreasing the optical output. As shown in the fifth to seventh experimental examples, when the n-type thickness ratio RTn and the p-type thickness ratio RTp are less than or equal to 3.75, the first angle θv of FFP is decreased while limiting a decrease in the optical output. In the eighth experimental example, while the first angle θv of FFP is the same as that in the seventh experimental example, the optical output is decreased to 91%.

### Advantages

As described above, the present embodiment has the following advantages.

(1) The semiconductor laser device 1A includes the light emitting unit 21 including the active layer 31 and the n-type semiconductor layer 32 and the p-type semiconductor layer 33 that sandwich the active layer 31 in the thickness-wise direction of the active layer 31. Light is emitted from the end surface of the active layer 31. The n-type semiconductor layer 32 of the semiconductor laser device 1A includes the first n-type cladding layer 34, which is located adjacent to the active layer 31, and the second n-type cladding layer 35, which is located at a side of the first n-type cladding layer 34 opposite from the active layer 31. The p-type semiconductor layer 33 includes the first p-type cladding layer 36, which is located adjacent to the active layer 31, and the second p-type cladding layer 37, which is located at a side of the first p-type cladding layer 36 opposite from the active layer 31. The thickness TN0 of the n-type semiconductor layer 32 is greater than the thickness TP0 of the p-type semiconductor layer 33. The n-type thickness ratio RTn, which is the ratio of the thickness TN1 of the first n-type cladding layer 34 to the thickness TN2 of the second n-type cladding layer 35, is equal to the p-type thickness ratio RTp, which is the ratio of the thickness TP1 of the first p-type cladding layer 36 to the thickness TP2 of the second p-type cladding layer 37. The n-type thickness ratio RTn and the p-type thickness ratio RTp are greater than 1.25 and less than or equal to 3.75.

In this structure, the first p-type cladding layer 36 and the second p-type cladding layer 37 allow traveling of light from the active layer 31 while restricting traveling of light to the desired range. The laser light L1 emitted from the light emitting unit 21 is increased in size in a direction perpendicular to the active layer 31. This decreases the first angle θv of FFP of the laser light L1 emitted from the light emitter 20 (the light emitting unit 21). Thus, divergence of the laser light L1 when emitted is limited. As described above, the semiconductor laser device 1A of the present embodiment improves the emission pattern property of the laser light L1 when emitted.

(2) The first n-type cladding layer 34 and the second n-type cladding layer 35 of the n-type semiconductor layer 32, which have the n-type thickness ratio RTn, restrict traveling of light to the desired range. Also, the first p-type cladding layer 36 and the second p-type cladding layer 37 of the p-type semiconductor layer 33, which have the p-type thickness ratio RTp, restrict traveling of light to the desired range. This avoids an undue size increase of the laser light L1in a direction perpendicular to the active layer 31 as indicated by the double-dashed line OL3 shown in FIG. 7. Thus, a decrease in the output of the laser light L1 when emitted is limited.

(3) In the semiconductor laser device 1A of the present embodiment, the n-type thickness ratio RTn is equal to the p-type thickness ratio RTp. If the n-type thickness ratio RTn differs from the p-type thickness ratio RTp, a peak 2NP may appear at a position shifted from the center as indicated by the double-dashed line shown in FIG. 8. In the present embodiment, the semiconductor laser device 1A emits the laser light L1 having a single peak 1SP in a direction perpendicular to the active layer 31.

(4) The laser light L1 emitted from the semiconductor laser device 1A of the present embodiment is coupled to a lens in a laser system to become, for example, parallel light. The first angle θv and the second angle θh of FFP of the laser light L1 affect the coupling efficiency to a lens. When the first angle θv and the second angle θh are large, the amount of the laser light L1 deviated from the lens is increased, and the laser light L1 is used less efficiently. In the semiconductor laser device 1A of the present embodiment, the first angle θv of FFP of the emitted laser light L1 is less than 25 degrees. Thus, the coupling efficiency of the laser light L1 to the lens is improved.

### Modified Examples

The embodiment may be modified, for example, as follows. The modified examples described below may be combined as long as there is no technical contradiction. In the following modified examples, the same reference characters are given to those elements that are the same as the corresponding elements of the above embodiments. Such elements will not be described in detail.

The structure of the semiconductor laser device 1A may be changed.

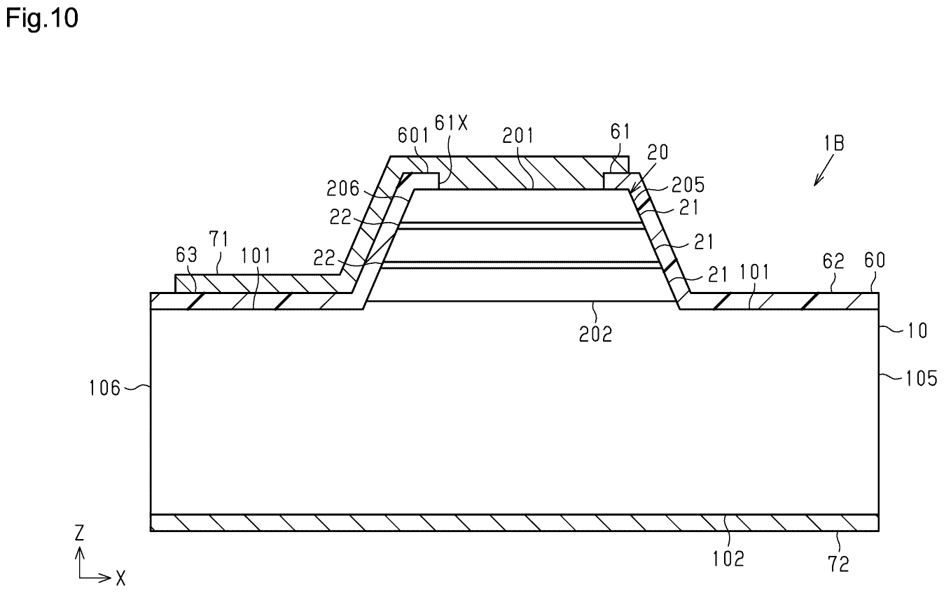

FIG. 10 is a diagram showing a modified example of a semiconductor laser device 1B.

In the semiconductor laser device 1B, the first electrode 71 extends from the electrode connection surface 201 of the light emitter 20 to the substrate cover 63 of the insulation film 60 covering the substrate main surface 101. The first electrode 71, which extends to the substrate main surface 101, may be connected to a pillar, a wire, or the like, to drive the semiconductor laser device 1B.

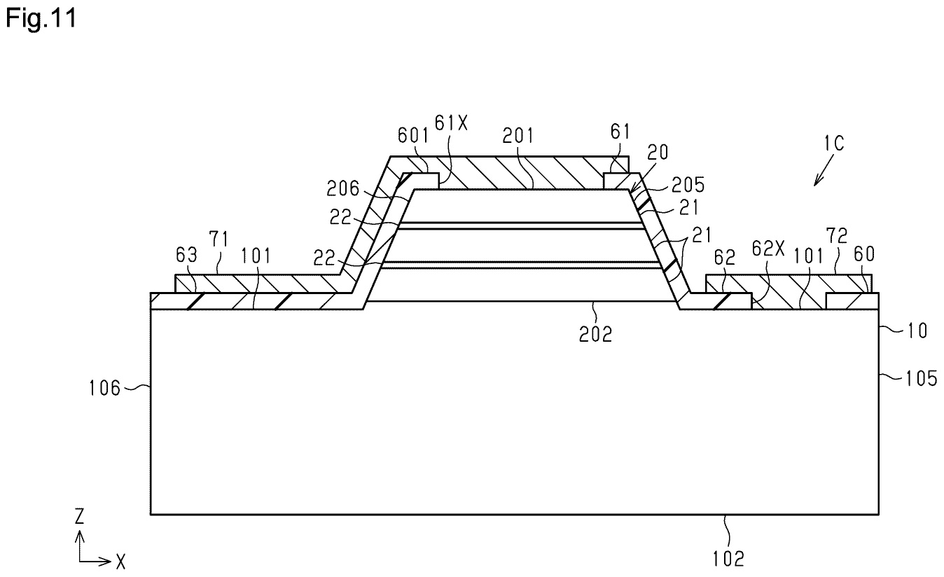

FIG. 11 is a diagram showing a modified example of a semiconductor laser device 1C.

In this modified example, the semiconductor laser device 1C includes the first electrode 71 that extends from the electrode connection surface 201 of the light emitter 20 to the substrate cover 63 of the insulation film 60 covering the substrate main surface 101 in the same manner as the semiconductor laser device 1B shown in FIG. 10. The semiconductor laser device 1C of this modified example includes a second opening 62X in the substrate cover 62 of the insulation film 60 that exposes part of the substrate main surface 101 of the semiconductor substrate 10. The second electrode 72 is electrically connected to the semiconductor substrate 10 exposed from the second opening 62X in the insulation film 60. The light emitter 20 is connected to the substrate main surface 101 of the semiconductor substrate 10. Thus, the second electrode 72 is electrically connected to the light emitter 20 by the semiconductor substrate 10. The light emitter 20 is connected between the first electrode 71 and the second electrode 72. As described above, the semiconductor laser device 1C is driven by the first electrode 71 and the second electrode 72, which are arranged at the side of the substrate main surface 101. The first electrode 71 and the second electrode 72, which are located at the side of the substrate main surface 101, allow for wire connection and flip-chip-mounting using pillars from the same side.

In the semiconductor laser device 1C of the modified example, the shape of the first electrode 71 may be identical to the shape of the first electrode 71 in the semiconductor laser device 1A of the embodiment. The shapes of the first electrode 71 and the second electrode 72 may be changed.

In the embodiment, the light emitter 20 includes three light emitting units 21 and two tunnel layers 22. However, the number of the light emitting units 21 is not limited to three and may be changed to any number. One, two, three or more light emitting units 21 may be formed. The number of the tunnel layers 22 is not limited to two and is adjusted in accordance with the number of the light emitting units 21.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

1. A semiconductor laser device, comprising:
a light emitting unit including an active layer, an n-type semiconductor layer, and a p-type semiconductor layer, the active layer being sandwiched between the n-type semiconductor layer and the p-type semiconductor layer in a thickness-wise direction of the active layer, and the semiconductor laser device being configured to emit light from an end surface of the active layer, wherein
the n-type semiconductor layer includes a first n-type cladding layer located adjacent to the active layer and a second n-type cladding layer located at a side of the first n-type cladding layer opposite from the active layer,
the p-type semiconductor layer includes a first p-type cladding layer located adjacent to the active layer and a second p-type cladding layer located at a side of the first p-type cladding layer opposite from the active layer,
a thickness of the n-type semiconductor layer is greater than a thickness of the p-type semiconductor layer,
an n-type thickness ratio is equal to a p-type thickness ratio, the n-type thickness ratio being defined as a ratio of a thickness of the first n-type cladding layer to a thickness of the second n-type cladding layer, and the p-type thickness ratio being defined as a ratio of a thickness of the first p-type cladding layer to a thickness of the second p-type cladding layer, and
each of the n-type thickness ratio and the p-type thickness ratio is greater than 1.25 and less than or equal to 3.75.

2. The semiconductor laser device according to claim 1, wherein
the first n-type cladding layer includes Al_{A1}Ga_{(1-A1)}As having an Al composition A1,
the first p-type cladding layer includes Al_{B1}Ga_{(1-B1)}As having an Al composition B1,
the Al composition A1 of the first n-type cladding layer is in a range of 0.3 to 0.4, and
the Al composition B1 of the first p-type cladding layer is in a range of 0.3 to 0.4.

3. The semiconductor laser device according to claim 2, wherein
the second n-type cladding layer includes Al_{A2}Ga_{(1-A2)}As having an Al composition A2,
the second p-type cladding layer includes Al_{B2}Ga_{(1-B2)}As having an Al composition B2,
the Al composition A2 of the second n-type cladding layer is in a range of 0.5 to 0. 6, and
the Al composition B2 of the second p-type cladding layer is in a range of 0.5 to 0. 6.

4. The semiconductor laser device according to claim 1, wherein the thickness of the first n-type cladding layer is greater than the thickness of the first p-type cladding layer.

5. The semiconductor laser device according to claim 4, wherein
the thickness of the first n-type cladding layer is in a range of 13000 angstroms to 27000 angstroms, and
the thickness of the first p-type cladding layer is in a range of 10000 angstroms to 20000 angstroms.

6. The semiconductor laser device according to claim 1, wherein the thickness of the second n-type cladding layer is greater than the thickness of the second p-type cladding layer.

7. The semiconductor laser device according to claim 6, wherein
the thickness of the second n-type cladding layer is in a range of 5000 angstroms to 11000 angstroms, and
the thickness of the second p-type cladding layer is in a range of 4000 angstroms to 8000 angstroms.

8. The semiconductor laser device according to claim 1, wherein the light emitting unit is a single light emitting unit.

9. The semiconductor laser device according to claim 1, wherein the light emitting unit is one of multiple light emitting units stacked in the thickness-wise direction.

10. The semiconductor laser device according to claim 1, wherein the light emitting unit is one of multiple light emitting units stacked with a tunnel layer sandwiched between the light emitting units.

11. The semiconductor laser device according to claim 1, wherein a divergence angle of light emitted from the light emitting unit in the thickness-wise direction is expressed as FFP that is less than 25 degrees.

12. The semiconductor laser device according to claim 1, wherein the light emitting unit emits laser light having a single peak in the thickness-wise direction.
